(19) United States
(12) Patent Application Publication
(10) Pub. No.: US 2011/0285518 A1
(43) Pub. Date: Nov. 24, 2011

(54) METHOD FOR DETECTING RUMBLE STRIPS ON ROADWAYS

(75) Inventors: Timothy J. Gordon, Ann Arbor, MI (US); Zeev Bareket, Ann Arbor, MI (US); Mark Gilbert, Ann Arbor, MI (US); Michael R. Hagan, Ann Arbor, MI (US)

(73) Assignee: THE REGENTS OF THE UNIVERSITY OF MICHIGAN, Ann Arbor, MI (US)

(21) Appl. No.: 12/783,233

(22) Filed: May 19, 2010

(51) Int. Cl. B60Q 1/00; G01R 23/16; G06F 19/00; G01M 99/00

(52) U.S. Cl. 340/425.5; 73/146; 702/76; 702/77

(57) ABSTRACT

A method and system for detecting the existence of rumble strips on a roadway by a vehicle. Wheel speed data is obtained from a wheel speed sensor, and frequency-based analysis is then performed on the wheel speed data. The presence of a rumble strip can then be detected based on the outcome of the frequency-based analysis. The wheel speed data can be modified before conversion to the frequency domain to reduce wheel-induced cyclic variations in wheel speed. The frequency-based analysis can use an FFT and a peak detection method that analyzes one or more peaks in the FFT data to determine if any are indicative of the presence of a rumble strip. The method can be carried out automatically in real time and used to alert the driver of the detection of the rumble strip.

### TECHNICAL FIELD

The invention relates to vehicles and, more particularly, to techniques for automated detection of rumble strips on the roadway.

### BACKGROUND OF THE INVENTION

Rumble strips are used on roadways to provide an audible and tactile warning to a vehicle driver that, for example, the vehicle has ventured near the edge of a road or lane. The rumble strips can be created in a variety of ways, such as by scalloping a section of road (e.g. the centerline or the road edge) in the direction of travel or by adding raised pavement markers. When the tire of a vehicle makes contact with the rumble strip, the driver can feel feedback from the vehicle structure and an audible noise will accompany this feedback. The audible/tactile warnings generated when the vehicle tire contacts a rumble strip rely on the vehicle driver to appreciate these warnings. However, it would be helpful to independently detect the presence of a rumble strip without relying on the vehicle driver's perception. Also, an automatic detection of the rumble strips can be employed to activate a crash prevention or mitigation system.

### SUMMARY OF THE INVENTION

In accordance with one aspect of the invention, there is provided a method of detecting the existence of rumble strips on a roadway by a vehicle. The method includes obtaining wheel sensor data from a wheel sensor on the vehicle, performing frequency-based analysis on the wheel sensor data, and detecting the presence of a rumble strip based on the outcome of the analysis. This method can be carried out automatically under software control to permit rumble strip detection without any action on the part of the driver.

In accordance with another aspect of the invention, there is provided a method of detecting the existence of rumble strips on a roadway by a vehicle. The method includes the steps of receiving angular wheel speed data from a wheel speed sensor that measures rotation of a vehicle wheel, selecting a portion of the received wheel speed data, modifying the selected wheel speed data such that wheel-induced cyclic variations in the selected wheel speed data are at least partially reduced, performing a Fourier Transform on the modified wheel sensor data and thereby producing frequency data for the wheel, determining that the wheel is on a rumble strip based on analysis of the frequency data, and generating a signal in response to the determination.

In accordance with yet another aspect of the invention, there is provided a method of detecting the existence of rumble strips on a roadway by a vehicle. The method includes the steps of receiving angular wheel speed data from a wheel speed sensor that measures rotation of a vehicle wheel, selecting a portion of the received wheel speed data, modifying the selected wheel speed data such that wheel-induced cyclic variations in the selected wheel speed data are at least partially reduced, performing a Fast-Fourier Transform of the modified wheel sensor data, identifying at least one peak in the output of the Fast-Fourier Transform, analyzing the peak by carrying out the following steps (1)-(5) using the output of the Fast-Fourier Transform: (1) determining a detection bandwidth centered on the peak, (2) determining a peak bandwidth that is located within the detection bandwidth and that is centered on the peak, (3) calculating a peak bandwidth area representing the area under the peak within the peak bandwidth, (4) calculating a detection bandwidth outer area representing the area within the detection bandwidth that is outside of the peak bandwidth, and (5) determining the ratio of the peak bandwidth area to the detection bandwidth outer area, then comparing the ratio to a predetermined threshold, and sending a signal that indicates a rumble strip is detected if the ratio is above the predetermined threshold.

### BRIEF DESCRIPTION OF THE DRAWINGS

Preferred exemplary embodiments of the invention will hereinafter be described in conjunction with the appended drawings, wherein like designations denote like elements, and wherein:

FIG. 1 is a block diagram depicting an example of a system that can be used to detect rumble strips on a roadway;

FIG. 2 is a flow chart depicting an example of a method that can be used to detect rumble strips on a roadway;

FIGS. 3-5 are plots of wheel sensor data during driving both off and on a rumble strip;

FIG. 6 is a graph showing an autocorrelation of an off-rumble strip portion of the wheel speed data of FIG. 5 superimposed with a cosine-based approximate of the autocorrelation;

FIG. 7 is the residual signal after subtracting the two waveforms of FIG. 6;

FIG. 8 is a Fast-Fourier Transform of the residual signal of FIG. 7;

FIG. 9 is a plot as in FIG. 6 for an on-rumble strip portion of the wheel speed data of FIG. 5;

FIG. 10 is a Fast-Fourier Transform of the residual signal of FIG. 9; and

FIG. 11 is an expanded portion of the graph of FIG. 10 illustrating some of the steps of the method of FIG. 2.

### DETAILED DESCRIPTION OF THE PREFERRED EMBODIMENTS

The system and method described below can be used on a vehicle to automatically detect whether the vehicle is in contact with a rumble strip. While wheel speed changes and measured acceleration can indicate the presence of potholes or other road deterioration, they can also signify that a vehicle tire is in contact with a roadway rumble strip. The disclosed system and method can identify the presence of rumble strips or other signaling roadway surface features while ignoring potholes and/or other road noise, and this can provide an added level of information to vehicle drivers or safety systems. By measuring the speed and identifying small changes in the rate of speed of a vehicle wheel, the variations in speed can then be analyzed to detect roadway rumble strips.

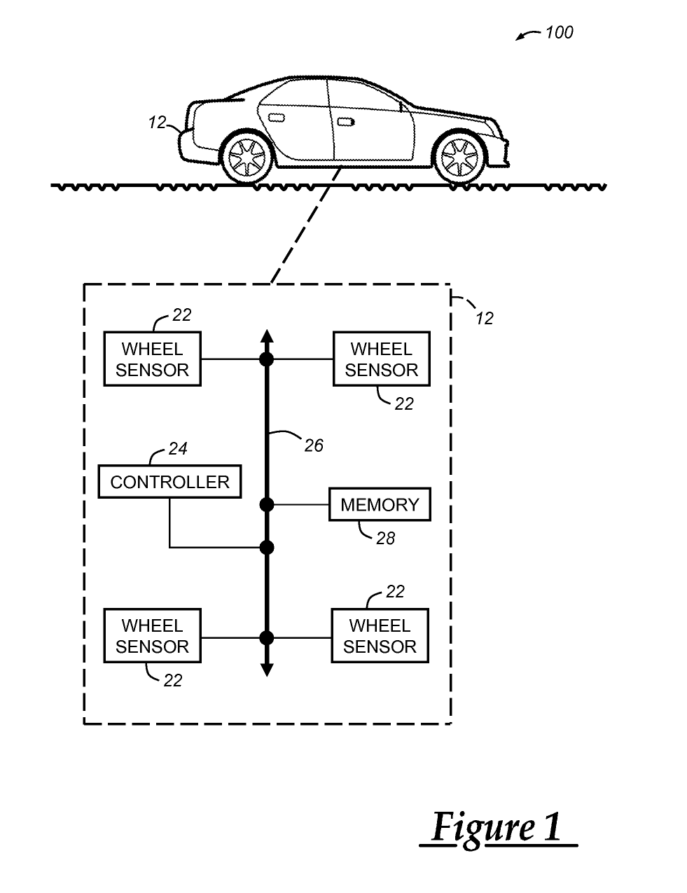

Various systems can be used to obtain wheel speed on the vehicle. For instance, manufacturers presently equip vehicles with anti-lock braking systems (ABS). Shown in FIG. 1 is a system 100 for detecting the presence of rumble strips that includes a vehicle 12 equipped with ABS. Generally, ABS involves the use of several components. These components include one or more wheel speed sensors 22, a controller 24, such as a central processing unit (CPU), one or more valves for releasing brake fluid pressure from a brake master cylinder at a locked wheel, and a pump for replacing the released brake fluid pressure. In the embodiment shown, the rumble strip detection system 100 and its method described herein can be implemented using an existing ABS system by adding suitable programming of the controller 24. In other embodiments, the system 100 can utilize one or more components dedicated to rumble strip detection only. The system can also be connected to the instrument panel or other user interface in the vehicle to provide a visual or audible warning in the event of rumble strip detection. Also, by enabling the detection of rumble strip engagement, the system can be useful in providing crash prevention and crash mitigation. Occurrences of rumble strip engagement by the vehicle can also be recorded in memory 28 or elsewhere for subsequent use.

Wheel speed sensors 22 indicate the rotational speed of a vehicle wheel. A location on a wheel hub, such as a wheel bearing, can include a toothed ring that rotates with the wheel hub. In a typical ABS system, the toothed ring includes 48 “teeth” around the circumference of the toothed ring. While this number of teeth is common, either fewer or greater numbers of teeth can be used with the system and method described herein. An inductive pickup or sensor is mounted in close proximity to the toothed ring and can detect the rotational speed of the wheel. This data from the sensor comprises a series of pulses, each of which represents a predetermined amount of angular rotation (e.g.,

$$\frac{2 π}{48}$$

radians for a 48-toothed ring). Non inductive speed sensors, such as optical sensors, as well as speed sensors that do not utilize teeth or other indicia on the hub can be used.

The wheel speed sensors 22 each send a signal to controller 24 which then processes the signals digitally to determine the presence or absence of a rumble strip at each wheel. The controller 24 can be any type of processing device capable of processing electronic instructions including microprocessors, microcontrollers, host processors, controllers, vehicle communication processors, and application specific integrated circuits (ASICs), central processing units (CPUs), or electronic control units (ECUs). It can be a dedicated processor used only for ABS and rumble strip detection, or can be shared with other vehicle systems over a vehicle bus 26. The controller 24 can execute various types of digitally-stored instructions, such as software or firmware programs stored in the controller or in memory 28, which enable the controller 24 to process received signals. Of course, it is not necessary to effectuate the methods described herein using an ABS system; other implementations are possible. As one example, it is also possible to install one or more speed sensors and a controller for receiving and processing the signal(s) from sensor(s) dedicated only to detect rumble strips and that do not participate in ABS.

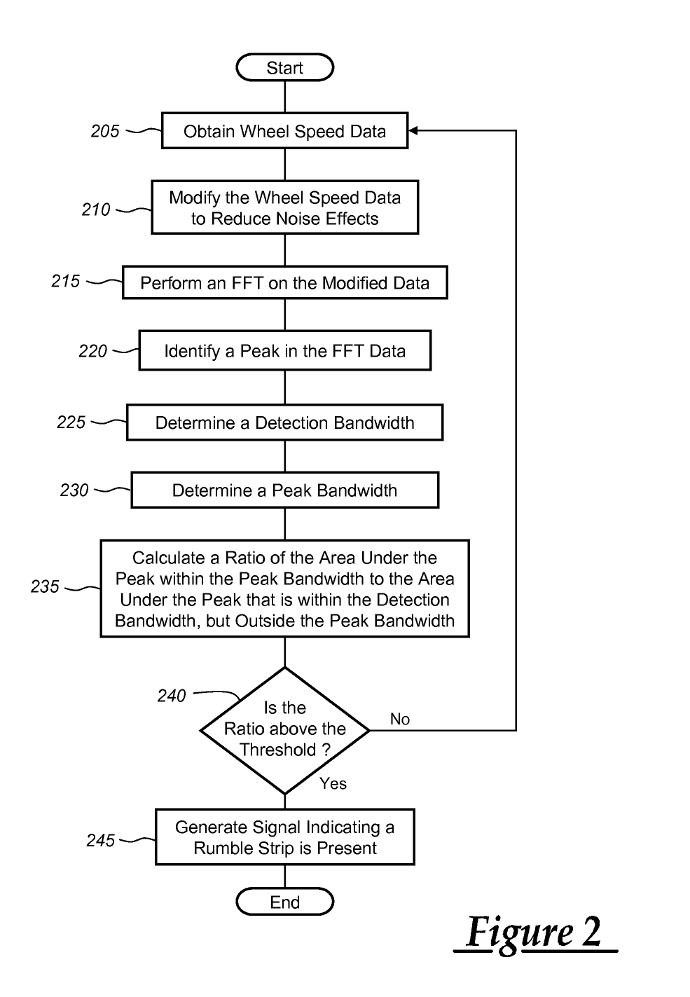

Turning to FIG. 2, there is shown an exemplary embodiment of a method 200 carried out by controller 24 to detect the existence of rumble strips on a roadway. The method 200 begins at step 205 by obtaining wheel speed sensor data from a wheel speed sensor 22. Wheel speed sensor data can be communicated via a signal that indicates the speed of a particular wheel on a vehicle 12; for example, by a pulse train the rate of which represents the angular speed of the wheel. This signal not only can indicate the speed of the wheel but also the acceleration of the wheel (i.e., the rate of change in speed). As the vehicle 12 moves, the stream of wheel speed sensor data is received by the controller 24, and that data can then be acquired for use in detecting rumble strips. Digital acquisition can be done in different ways known to those skilled in the art; for example, by sampling the speed sensor data at a suitable sampling rate which can be tied to the resolution of angular measurement available via each sensor. Accuracy can be improved by increasing the sampling rate or increasing the number of samples (i.e. amount of data) taken. However, these improvements can involve tradeoffs such as requiring a more sophisticated controller or causing a decreased response time (increased latency), respectively. In one exemplary embodiment, the wheel speed sensor data can be sampled at a rate above 100 KHz to help ensure adequate accuracy of analysis.

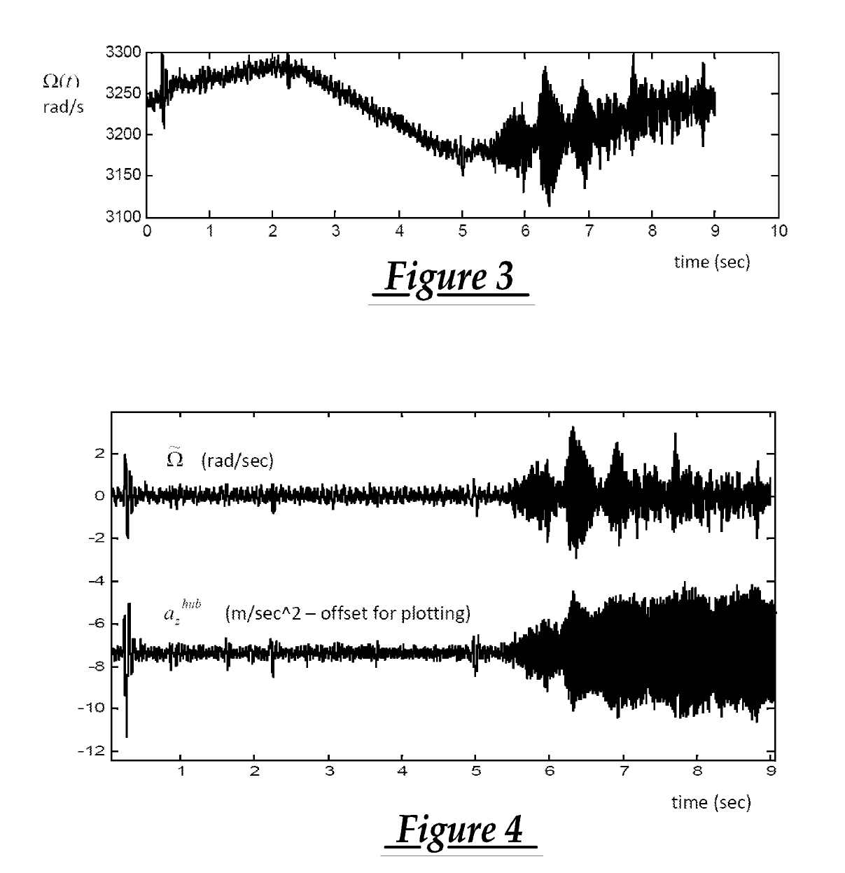

Once acquired, the digitized angular speed, represented as Ω(t), can be processed for each wheel by the controller 24. An example of this angular speed data Ω(t) is shown in FIG. 3, representing measured data for a vehicle traveling 50 mph and encountering a rumble strip at about time t=5.5 seconds. The signal includes a slow variation due to changes in vehicle speed by the driver, and this can be removed using a simple filter (e.g., a median filter), as discussed below. To process the received wheel speed signal, a selected portion of the data is first obtained, and this can be done as a part of step 205. This selection of a portion of the total received wheel speed data can be done by obtaining a portion of the data that represents a selected total angular rotation of the wheel. This can be done, for example, by selecting a portion of the data that comprises a selected number of pulses of the wheel speed data; for example, 96 pulses representing two full rotations of the wheel. Using angular displacement instead of a selected time period reduces the impact of vehicle speed on the subsequent analysis.

At step 210, the obtained wheel speed sensor data is modified to reduce noise effects so as to, for example, compensate for inherent wheel imbalances. These imbalances cause small variations in measured angular wheel speed and hub vertical acceleration, and are the result of such things as unequal angular weight distribution about the wheel, tire stiffness variations, as well as run-out of the tire, rim, or both. Even with balancing weights, the wheel can exhibit cyclic variations in speed that are detected via the sensors 22. Road surface noise can also affect the sensor measurements. Thus, the overall wheel rotation frequencies, harmonics, or other vibrations can be periodic or they can also be random; either way it is helpful to remove these speed variations from the received wheel speed signal data. And removal can be effected in a variety of ways. For instance, the wheel-induced cyclic vibrations can be removed from the angular speed Ω(t) in the time domain, frequency domain, or partially in both.

In accordance with one embodiment, the angular speed Ω(t) can be filtered in the time domain before carrying out the frequency-based analysis described below. This can be done, for example, using commercially available software from Mathworks, such as Matlab™, which includes software capable of smoothing the received wheel speed sensor data before frequency analysis is performed. As a first step, a three-point median filter (Matlab function medfilt1) can be used to remove data outliers to thereby generate a filtered angular speed \tilde{Ω}=Ω− Ω̅_{med}. For the 48-toothed wheel measurement described above, a 48 point median filter can be used for this, corresponding to a 48 point window that represents a full wheel rotation. This is useful for removing, for example, variations in vehicle speed caused by the driver. FIG. 4 depicts the resulting signal \tilde{Ω} after applying the median filter. Also shown in FIG. 4 is the wheel hub vertical acceleration which can be measured by an accelerometer placed in a suitable location at the wheel. As shown in that figure, the acceleration correlates to the speed changes due to the rumble strip, such that either wheel speed or acceleration can be used for rumble strip detection. Similarly, longitudinal acceleration can be measured and used in lieu of or in addition to wheel speed or vertical acceleration.

After the initial filtering, the signal \tilde{Ω} is then further modified to account for the wheel-induced cyclic variations due to, for example, wheel imbalances. For this second modification of the speed data an autocorrelation of the filtered signal \tilde{Ω} is taken which helps emphasize the periodic nature of the wheel speed sensor data signal. The autocorrelation function can use frequency-based variables to define a waveform:

$$F ( θ , {θ}_{0} ) = {N}^{- 1} {\sum }_{k} \tilde{Ω} ( {θ}_{0} + k φ ) \tilde{Ω} ( {θ}_{0} + θ + k φ )$$

The variable θ₀ denotes a wheel rotation angle at the center of a data window, φ represents a nominal angular spacing between wheel sensor poles (e.g. each tooth on the toothed ring—in this case,

$$φ = \frac{2 π}{48} ) ,$$

and N equals the number of inputs or points in the data window. This function F can be carried out in Matlab using the function xcorr. Of course, it is envisioned that other software or calculations can be used for this purpose, whether it is application-specific or generally available.

Off the rumble strip, it is expected that a large part of the variation in F will be cyclic. These variations can be removed using a corresponding waveform that is fit to F and that can be represented by the following equation:

$$\hat{F} ( θ , {θ}_{0} ) = A ( {θ}_{0} ) ( 1 - \frac{θ}{4 π} ) cos θ$$

where A is a fitted amplitude determined by the following regression equation:

$$\{ \begin{matrix}⋮ \\ F ( {θ}_{i} ) \\ ⋮\end{matrix} \} = \{ \begin{matrix}⋮ \\ ( 1 - \frac{{θ}_{i}}{4 π} ) cos {θ}_{i} \\ ⋮\end{matrix} \} \cdot A$$

Modified wheel sensor data can then be created by subtracting this cosine-based wheel periodicity \hat{F} from the autocorrelation F. The modified wheel sensor data comprises the residual signal left over after this subtraction: Fᵣₑₛ=F−\hat{F}. This residual signal may then be substantially free from cyclic vibrations.

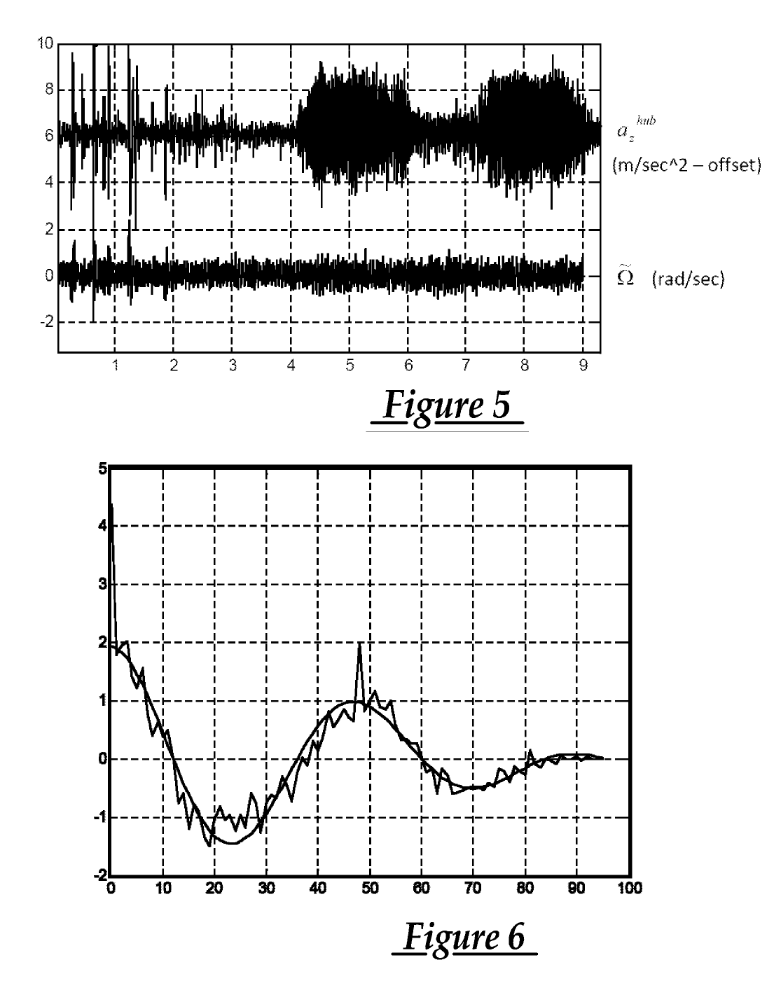

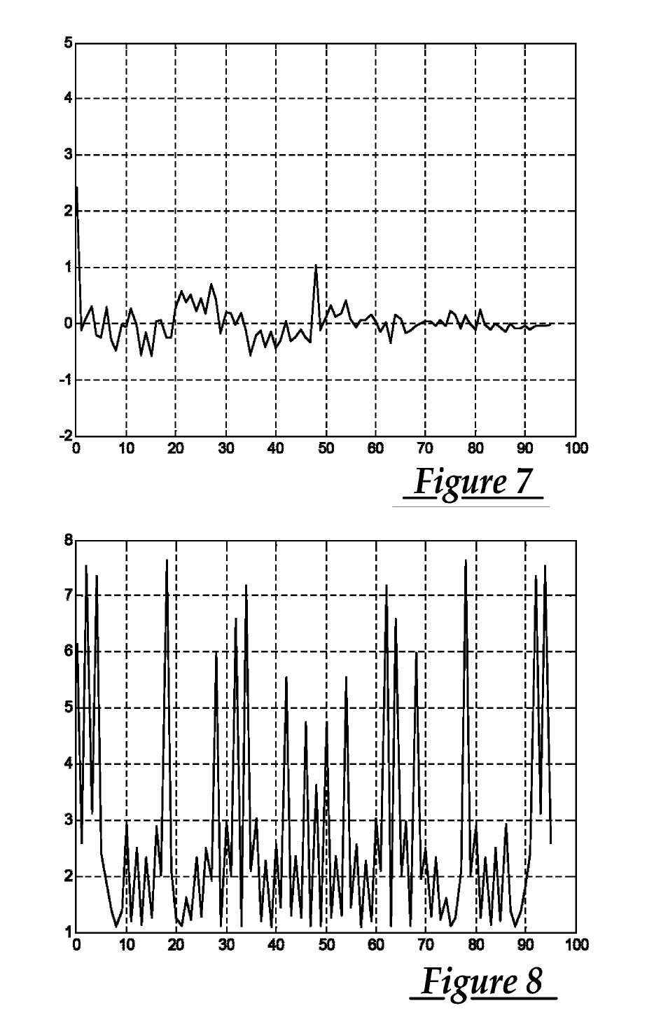

This modification of the signal \tilde{Ω} is shown graphically in the figures. FIG. 5 depicts again a sample of measured angular wheel speed data, this time for a vehicle traveling at 80 mph and encountering a rumble strip beginning just after four seconds. Where the wheel is off the rumble strip (e.g., at a window at about 3.5 seconds), FIG. 6 shows both the autocorrelation F of the signal \tilde{Ω} and the cosine-based wheel periodicity \hat{F}. The difference Fᵣₑₛ between these two signals is shown in FIG. 7.

Referring back to FIG. 2, after modifying the selected wheel speed data, frequency-based analysis is begun which, for the illustrated embodiment, is carried out using the residual autocorrelation data Fᵣₑₛ. This autocorrelation data comprises one form of modified wheel sensor data with which the disclosed method and system can be used. Other types of modified wheel sensor data can be used in other embodiments for the frequency-based analysis, as will be appreciated by those skilled in the art. Thus, at step 215, the residual signal Fᵣₑₛ is converted to the frequency domain; e.g, by applying a Fourier Transform to the modified wheel sensor data. Preferably, a Fast-Fourier Transform (FFT) is used for this purpose. This results in conversion of the residual signal to frequency data covering a spectrum of frequencies that, in the event of a rumble strip, will include at least one peak located a particular frequency that is different than the frequency that corresponds to the cyclic wheel rotation. Although the wheel-induced cyclic vibrations can be removed prior to conversion to the frequency domain, as described above, they can be filtered out or otherwise removed at the same time or after the FFT operation is performed. And the FFT can be carried out using software commonly available. Matlab™ software produced by Mathworks includes the FFT function for performing a FFT, but other software capable of carrying out an FFT can also be used.

FIG. 8 depicts the FFT of the residual signal Fᵣₑₛ of FIG. 7. In this FFT plot, the frequency units along the x-axis are equivalent to a time-based FFT, where for a data window of duration T seconds, the interval of frequency spacing is 1/T cycles per second. In the example used herein, the data window corresponds to 2 revolutions of the wheel (i.e., 4π radians), so the unit of frequency spacing is ¼π cycles per radian. The basic wheel rotation frequency is ½π cycles per radian, corresponding to f=2 in FIG. 8. Because of the usual aliasing property of a sampled data FFT, the peak has a mirror image at f=96−2=94. After removing the cyclic variation induced by the wheel, FIG. 8 shows that what is left over is almost exclusively noise. Although some of the basic wheel cycle is still shown (at f=2 and f=94), they are reduced to the same low-level peaks as the noise through the rest of the FFT.

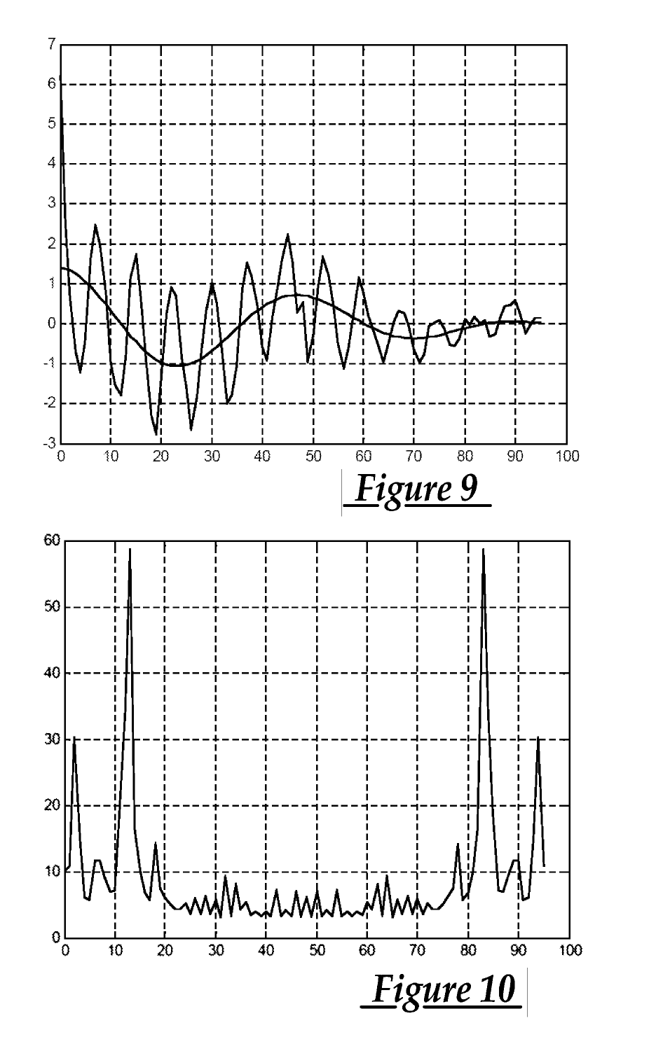

When the wheel is on the rumble strip, the result is notably different. FIG. 9 depicts the autocorrelation F (and its fitted approximate \hat{F}) of a portion of the FIG. 5 signal \tilde{Ω} during a time when the wheel is on the rumble strip. Although the fitted cosine function removes most of the wheel-induced cyclic variation, there remains a higher frequency variation corresponding to the wheel angular displacement caused by the rumble strip. FIG. 10 depicts the FFT of the residual signal Fᵣₑₛ which, as compared to the plot of FIG. 8, includes a notable peak at about f=12.5 (and f=83.5) due to the rumble strip.

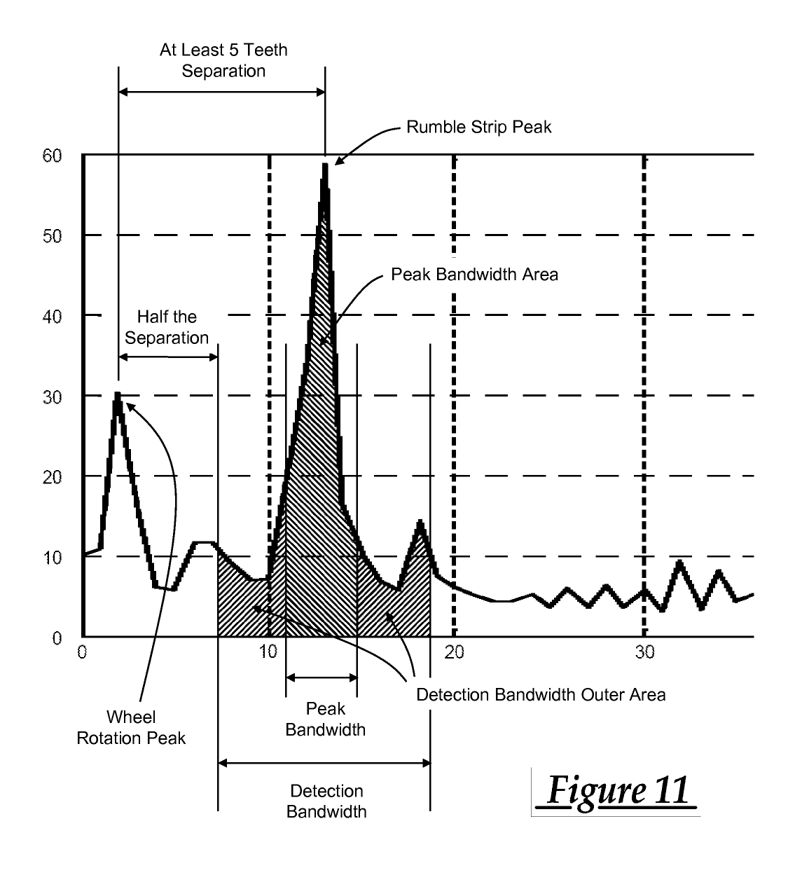

To detect this peak and thereby determine the presence of the rumble strip, a detection method is used which involves analysis of the frequency data from the FFT. Thus, at step 220 of FIG. 2, one or more peaks are located in the output of the FFT. Graphically, this can be seen by reference to FIG. 11 which is an expanded plot of the first portion of the FFT plot of FIG. 10. Detection of the peaks in the FFT data can be carried out in any suitable manner, as will be known to those skilled in the art. Smaller peaks can be ignored, for example, by using a minimum amplitude threshold below which any peak is ignored as noise As can be seen in FIG. 11, the FFT data contains a number of peaks, two of which are dominant in this lower band of frequencies. The first of these dominant peaks occurs at f=2 and corresponds to the wheel periodicity. The second peak, at f=12.5 (and any other peak of interest), can be analyzed in any of a number of different ways to determine whether or not a rumble strip is present. Generally, this involves determining a characteristic of the peak and determining if that characteristic is indicative of the presence of the rumble strip. For example, the existence of a peak above a selected amplitude threshold and at a frequency other than the wheel periodicity can be taken as an indication of a rumble strip. Alternatively, the narrowness of the peak, either alone or in combination with its amplitude, can be used as an indication of the rumble strip. This “narrowness” of the peak can be determined, for example, using the steps 225-240 of FIG. 2 to thereby robustly determine the presence or absence of a rumble strip.

In step 225, a detection bandwidth is determined, covering a range of frequencies that includes the particular frequency at which the peak is located (e.g., 12.5). And, at step 230, a peak bandwidth is determined, which is a narrower band of frequencies that also includes the peak frequency. Preferably, both the peak and detection bandwidths are centered on the peak frequency. An example of this is shown in FIG. 11. The range of frequencies covered by the two bandwidths can be selected as desired. For example, the peak bandwidth can comprises one to two frequency units on either side of the peak frequency while the detection bandwidth can include a larger number (such as three or more times the length of the peak bandwidth). In the illustrated example, the lower boundary of the detection bandwidth is selected at a point (f=7) about halfway between the wheel rotation peak frequency (f=2) and the rumble strip peak frequency (f=12.5), and the upper boundary is a similar distance on the other side of the rumble strip peak frequency, at f=18.

Once the peak and detection bandwidths are determined, then at step 235 a ratio is calculated which provides an indication of the extent to which the signal at the peak is confined to a narrow range of frequencies. This ratio is that of the area under the curve within the peak bandwidth, divided by the area within the detection bandwidth that is outside of the peak bandwidth:

$$Ratio = \frac{Peak Bandwidth Area}{Detection Bandwidth Outer Area}$$

If the ratio is above a predetermined level or threshold, it can indicate that a high proportion of non-cyclic variations in the angular velocity variations of a vehicle wheel are located within a narrow frequency band and a high likelihood exists that a vehicle wheel is in contact with a rumble strip. Again, this calculation as well as the other steps of method 200 can take place on the vehicle 12 using the controller 24 or other suitable computing resources, and this can be done in real time to monitor for a rumble strip while driving. If desired or necessary, the resolution of the processed input signal Ω(t) and, thus, the accuracy of the analysis can be improved further by increasing the amount of data sampled, such as by sampling data over additional wheel rotations. However, increasing the amount of data sampled may also increase the latency (delay time) of a real-time system. In one exemplary embodiment, two wheel revolutions (e.g. 96 points) can be sufficient to extract narrow-band peaks while maintaining adequate response time of the system.

At step 240, the calculated ratio is compared to a predetermined threshold and if the calculated ratio is above the predetermined threshold, a signal is generated that indicates a rumble strip is detected at step 245. Predetermined thresholds, such as relevant ratio threshold values, can be specified by vehicle designers and stored at the vehicle 12. The calculated ratio can be compared to the ratio thresholds and it can be determined whether the ratio is above or below the relevant ratio thresholds. If the ratio is below the relevant ratio thresholds, the controller 24 can determine that a rumble strip is not present, in which case the method 200 then returns to step 205 to process another peak in the data or to begin processing another window of data. Alternatively, if the calculated ratio is above the threshold, the controller 24 can generate a signal (e.g., on the vehicle bus 26) communicating this situation to the driver or for recording purposes. The method 200 then ends.

As will be appreciated by those skilled in the art, the system and method described above permits real-time, automated determination of a rumble strip under any of the vehicle wheels during driving of the vehicle. The detection of the rumble strip can then be visually, audibly, or tactilely signaled to the driver and/or recorded for insurance or other evidentiary purposes.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example”, “for instance”, “such as”, and “like”, and the verbs “comprising”, “having”, “including”, and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

1. A method of detecting the existence of rumble strips on a roadway by a vehicle, comprising:
(a) obtaining wheel sensor data from a wheel sensor on the vehicle;
(b) performing frequency-based analysis on the wheel sensor data; and
(c) detecting the presence of a rumble strip based on the analysis.

2. The method of claim 1, wherein the wheel sensor comprises a wheel speed sensor and wherein the wheel sensor data comprises wheel speed data.

3. The method of claim 1, wherein the wheel sensor comprises an accelerometer oriented to measure vertical or longitudinal acceleration, or both, that results when the wheel engages a rumble strip during driving of the vehicle.

4. The method of claim 1, wherein step (b) comprises generating frequency data covering a spectrum of frequencies and including at least one peak located at an particular frequency that is different than a frequency corresponding to cyclic wheel rotation.

5. The method of claim 4, wherein step (b) further comprises selecting the peak from among a plurality of peaks at different frequencies.

6. The method of claim 4, wherein step (c) further comprises detecting the presence of the rumble strip based on a characteristic of the peak.

7. The method of claim 4, wherein step (b) further comprises determining one or more characteristics of the peak located within a detection bandwidth covering a range of frequencies that includes the particular frequency of the peak, and wherein step (c) further comprises detecting the presence of the rumble strip based on at least one of the characteristic(s) of the peak.

8. The method of claim 7, wherein step (b) further comprises determining a lower boundary of the detection bandwidth that is located between the particular frequency of the peak and the frequency corresponding to cyclic wheel rotation.

9. The method of claim 7, wherein step (b) further comprises selecting the detection bandwidth such that the particular frequency of the peak is centered in the detection bandwidth.

10. The method of claim 7, wherein step (b) further comprises determining a peak bandwidth that is located within the detection bandwidth and that includes the particular frequency of the peak, and wherein step (c) further comprises detecting the presence of the rumble strip based on characteristics of the frequency data in both the peak bandwidth and detection bandwidth.

11. The method of claim 7, wherein step (b) further comprises:
determining a peak bandwidth that is located within the detection bandwidth and that includes the particular frequency of the peak;
calculating a peak bandwidth area using the frequency data within the peak bandwidth;
calculating a detection bandwidth outer area using the frequency data within the detection bandwidth that is outside the peak bandwidth; and
determining the ratio of the peak bandwidth area to the detection bandwidth outer area; and
wherein step (c) further comprises detecting the presence of the rumble strip based on the ratio being above a selected threshold.

12. The method of claim 1, wherein step (b) further comprises the steps of:
modifying the wheel sensor data such that wheel-induced cyclic variations in the wheel sensor data are at least partially reduced; and
carrying out a Fourier transformation of the modified wheel sensor data, thereby producing frequency data for the modified wheel sensor data; and
wherein step (c) further comprises detecting the presence of the rumble strip based on at least one characteristic of the frequency data.

13. The method of claim 1, wherein step (a) further comprises measuring the wheel sensor data at a frequency greater than 100 KHz.

14. The method of claim 1, wherein steps (a) through (c) are carried out in real time during operation of the vehicle by a driver, and wherein the method further comprises the step of alerting the driver of the presence of the rumble strip following step (c).

15. A method of detecting the existence of rumble strips on a roadway by a vehicle, comprising:
(a) receiving angular wheel speed data from a wheel speed sensor that measures rotation of a vehicle wheel;
(b) selecting a portion of the received wheel speed data;
(c) modifying the selected wheel speed data such that wheel-induced cyclic variations in the selected wheel speed data are at least partially reduced;
(d) performing a Fourier Transform on the modified wheel speed data and thereby producing frequency data for the wheel;
(e) determining that the wheel is on a rumble strip based on analysis of the frequency data; and
(f) generating a signal in response to the determination.

16. The method of claim 15, wherein step (a) comprises receiving the wheel speed data as a series of pulses, each of which represents a predetermined amount of angular rotation of the wheel, and wherein step (b) comprises using a portion of the series of pulses having a selected number of pulses representing a selected total angular rotation of the wheel.

17. The method of claim 15, wherein step (c) comprises performing an autocorrelation on the selected wheel sensor data and subtracting cosine-based wheel periodicity from the autocorrelated wheel sensor data.

18. The method of claim 15, wherein step (d) further comprises producing FFT data by performing a Fast-Fourier Transform (FFT) on the modified wheel speed data, and wherein step (e) further comprises detecting a peak in the FFT data and carrying out the determination by based on a relationship between a characteristic of the peak in a first bandwidth and the characteristic of the peak in a second bandwidth that is larger than and includes the first bandwidth.

19. The method of claim 15, wherein step (a) further comprises receiving angular wheel speed sensor data from an ABS wheel sensor.

20. A method of detecting the existence of rumble strips on a roadway by a vehicle, comprising:
(a) receiving angular wheel speed data from a wheel speed sensor that measures rotation of a vehicle wheel;
(b) selecting a portion of the received wheel speed data;
(c) modifying the selected wheel speed data such that wheel-induced cyclic variations in the selected wheel speed data are at least partially reduced;
(d) performing a Fourier Transform of the modified wheel sensor data;
(e) identifying at least one peak in the output of the Fourier Transform;
(f) analyzing the peak by carrying out the following steps using the output of the Fourier Transform:
(f1) determining a detection bandwidth centered on the peak;
(f2) determining a peak bandwidth that is located within the detection bandwidth and that is centered on the peak;
(f3) calculating a peak bandwidth area representing the area under the peak within the peak bandwidth;
(f4) calculating a detection bandwidth outer area representing the area within the detection bandwidth that is outside of the peak bandwidth;
(f5) determining the ratio of the peak bandwidth area to the detection bandwidth outer area; and
(g) comparing the ratio to a predetermined threshold; and
(h) sending a signal that indicates a rumble strip is detected if the ratio is above the predetermined threshold.
